(19) United States
(12) Patent Application Publication
(10) Pub. No.: US 2025/0063881 A1
(43) Pub. Date: Feb. 20, 2025

(54) PHOTOVOLTAIC APPARATUS

(71) Applicant: Universal Display Corporation, Ewing, NJ (US)

(72) Inventor: Michael HACK, Carmel, CA (US)

(21) Appl. No.: 18/760,464

(22) Filed: Jul. 1, 2024

Related U.S. Application Data
(60) Provisional application No. 63/519,597, filed on Aug. 15, 2023.

(51) Int. Cl. H10K 30/88

(52) U.S. Cl. CPC H10K 30/88

(57) ABSTRACT

A device is provided that includes a first photovoltaic (PV) cell on a first substrate and a second substrate adjacent to the first PV. The first PV cell has a first transparency and a first efficiency. A first portion of light is absorbed by the first PV based on the first efficiency to generate electricity. The second substrate is adjacent to the first PV. A second portion of light passes through the first OPV based on the first transparency and passes through the second substrate.

### CROSS-REFERENCE TO RELATED APPLICATIONS

This application claims priority to U.S. Patent Application Ser. No. 63/519,597, filed Aug. 15, 2023, the entire contents of which are incorporated herein by reference.

### FIELD

The present invention relates to organic emissive devices having inverted and non-inverted organic light emitting diode structures, as well as organic photovoltaic devices, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or subcells.

In addition to the pursuit of high device efficiency, OPVs have unique advantages, such as the application of semi-transparent solar cells for use in building integrated photovoltaics (BIPV). Considering the vast surface areas of windows and facades in modern urban environments, developing semi-transparent solar cells with both high efficiency and transmittance has become increasingly important. For a solar cell to be highly transparent, visible light would have to travel uninhibited to the eye, and hence cannot be absorbed. Selectively harvesting near-infrared (NIR) radiation avoids competition between efficiency and transmittance. However, the lack of high performance NIR absorbers in conventional fullerene based OPVs has prevented the attainment of efficient, yet highly transparent (in the visible) devices. To date, semi-transparent OPVs based on fullerene acceptors show only PCE less than or equal to 4% with average visible transmittance of 61%.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

A device is provided that includes a first photovoltaic (PV) cell on a first substrate and a second substrate adjacent to the first PV. The first PV may be an organic PV (OPV). The first PV cell has a first transparency and a first efficiency. A first portion of light is absorbed by the first PV based on the first efficiency to generate electricity. The second substrate has as second transparency. A second portion of light passes through the first PV based on the first transparency and passes through the first substrate. The second substrate of the device may have a second transparency and may be adjacent to the first OPV and on an opposite side of the first PV from the first substrate. The second substrate may be a protective barrier. The electricity generated by the first portion of light absorbed by the first PV may exceed the heat flow caused by the second portion of light under ambient solar irradiation. The first PV may be a thin film solar cell. The thin film solar cell may be an organic thin film solar cell, a CdTe (cadmium telluride) solar cell, and/or a perovskite solar cell. The first PV may be closer to the ambient light than the first substrate. The first substrate may be glass or plastic. The first substrate or the second substrate may be tinted glass, and the first PV may be a thin film solar cell that is an organic thin film solar cell, a CdTe (cadmium telluride) solar cell, and/or a perovskite solar cell. The first PV may have a first transparency greater than 40% and a first efficiency greater than 8%. The first PV may have a first transparency greater than 40% and a first efficiency greater than 10%. The first PV may have a first transparency greater than 60% and a first efficiency greater than 5%. The first PV may have a first transparency greater than 60% and a first efficiency greater than 7%. The first PV may have a first transparency that is greater than 40% and the first substrate may have a second transparency greater than 40%. The first PV may have a first transparency that is greater than 30% and the first substrate may have a second transparency greater than 60%. The first PV may have a first transparency that is greater than 60% and the first substrate may have a second transparency greater than 20%. The first substrate has a second transparency less than 50%. The second portion of light may pass through the second substrate based on the second transparency.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example of a basic structure for a sunroof incorporating tinted glass reduce heat flow into the vehicle and a semi-transparent photovoltaic (PV) solar cell according to an embodiment of the disclosed subject matter.

FIG. 4 shows example calculations for sunroof glass transparency to solar cell transparency such that electricity generated exceeds heat flow into the vehicle for PV with 18% opaque cell efficiency according to an embodiment of the disclosed subject matter.

FIG. 5 shows example calculations for sunroof glass transparency to solar cell transparency such that electricity generated exceeds heat flow into the vehicle for PV with 12% opaque cell efficiency according to an embodiment of the disclosed subject matter.

FIG. 6 shows a plot of sunroof glass transparency (VLT) vs solar cell transparency such that electric generated exceeds heat flow into the vehicle for PV with both 12% and 18% opaque cell efficiency according to an embodiment of the disclosed subject matter.

FIG. 7 shows a single-junction organic photovoltaic cell according to an embodiment of the disclosed subject matter.

FIG. 8 shows a multi-junction and/or tandem organic photovoltaic cell according to an embodiment of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

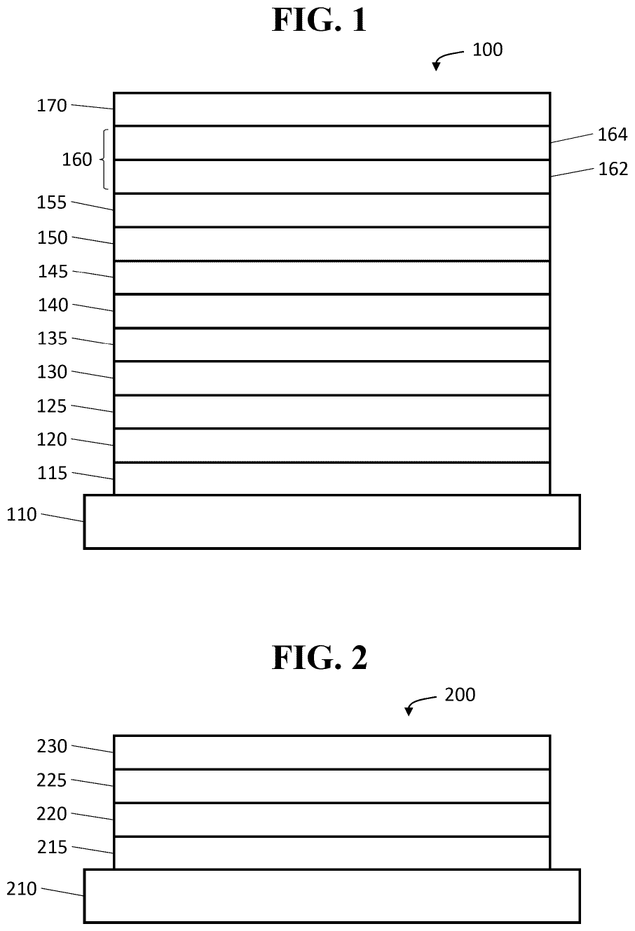

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg: Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18° C. to 30° C., and more preferably at room temperature (20-25° C.), but could be used outside this temperature range, for example, from-40° C. to 80° C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used may be a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

There is a growing trend to place sunroofs in cars and other modes of transportation. Similarly, there is a growing trend to place tinted windows in buildings, homes, and other structures. While larger window areas are more attractive, they can let in more heat which can be very undesirable.

Transparent organic photovoltaic (TOPV) devices may be used for generating power in windows, as it provides visual performance by having both spatially uniform and generally spectrally uniform characteristics and absorption across the visible spectrum, and may be configured to absorb infra-red radiation (and convert such radiation into electricity). These devices may be configured to reduce the heat passing through such a window, skylight, or sunroof into a vehicle, building, or structure. The window, skylight, or sunroof of the vehicle, building, or structure may be tinted to reduce the visible light transmission (VLT) and to control the heat flowing through the window, skylight, or sunroof of the vehicle, building, or structure.

In some embodiments, other thin film photovoltaic devices may be included in a window, skylight, and/or sunroof, in addition to the PV and/or organic photovoltaic (OPV) devices described throughout. OPV devices may be preferred, as such devices may be made to have generally spectrally uniform characteristics and absorption across the visible spectrum (e.g., 400-700 nm) and absorb in the near infra-red. Both CdTe (cadmium telluride) and/or perovskites may absorb visible light and may convert the received light efficiently into electricity. When CdTe and/or perovskites are configured to be thin, they may be semi-transparent. In some configurations, the thin CdTe and/or perovskites may have a reddish tint as they absorb blue light. These configurations of CdTe and/or perovskites may be relatively transparent to red light.

Implementations of the disclosed subject matter provide a window, skylight, and/or sunroof configured with TOPV such that the electricity generated exceeds the amount of heat entering the vehicle, building, or structure so cooling can be applied to counteract the heat entering the vehicle, building, or structure without any external power being required. Hence, there is a net zero transparent PV and/or OPV window, sunroof, or the like.

Embodiments of the disclosed subject matter may use transparent PV and/or OPV, or semi-transparent PV and/or OPV, in windows as it can transmit visible light but absorb and convert near infra-red (NIR) and/or ultraviolet light into electricity. This may have the benefit of producing electrical power, providing a highly pleasing visual appearance (i.e., can appear as spatially uniform neutral tint across the whole window area), and/or may reduce infra-red heating of the vehicle, building, or structure by converting NIR into electricity.

Tint may be constant across visible spectrum and so the window, skylight, and/or sunroof may appear gray, or may be configured to transmit some visible wavelengths more than other visible wavelengths, where an effective color is based on the specifics of the visible wavelengths that are transmissible.

Other approaches to embedding PV into windows have relied on using PV regions of less transmissive solar cells embedded into the window, where electricity is only generated in a PV region and most of the light is transmitted outside of these PV regions.

To ensure that more energy is not required to remove excess heat flowing through the window, skylight, and/or sunroof, the PV and/or OPV of the disclosed subject matter may generate more electricity than the window, skylight, and/or sunroof allows heat to flow across the respective window, skylight, and/or sunroof. Such embodiments may provide a net zero energy balance, and the generated electricity may be used to apply and/or power cooling to offset the incoming heat.

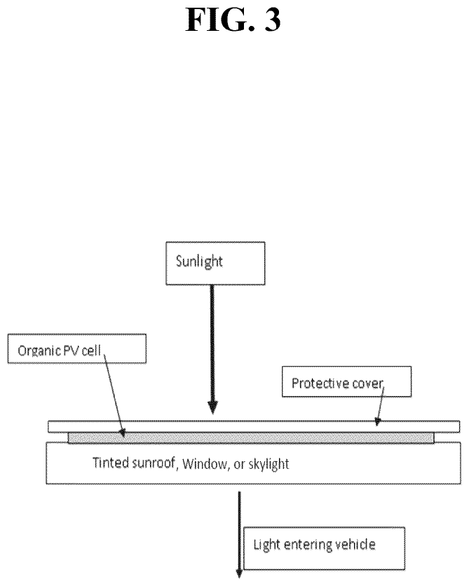

Use of a tinted window will reduce heat flow into a vehicle. In addition, the PV and/or OPV solar cell may be tuned to provide a specific optical transmission (e.g., the visible light spectrum of 400 nm-700 nm). FIG. 3 shows a sunroof, window, and/or skylight having a semi-transparent PV and/or OPV and tinted glass to reduce heat flow according to an embodiment of the disclosed subject matter. As shown in FIG. 3, an optional protective cover may be configured to receive sunlight, and at least a portion of light may be absorbed by the PV and/or OPV cell, and a portion of the light may be transmitted through the PV and/or OPV cell and into the tinted sunroof, window, and/or skylight (i.e., substrate). A portion of light may be transmitted through the tinted sunroof, window, and/or skylight and may enter the vehicle, building, or structure.

The overall optical transmission of the sunroof, skylight, and/or window may be the product of the PV and/or OPV cell transparency (“TOPV” as used throughout) and the glass window transparency (“GLASS” as used throughout). In an embodiment, the glass window transparency may be the transparency of any substrate, including but not limited to, glass. The basic criteria for ensuring net zero energy consumption balancing electricity generation versus heat flow into the vehicle may be shown below in Formula 1. Here, 375 W/m² may be visible light radiation under AM1.5 conditions (i.e., where 1.5 is an atmosphere thickness which corresponds to a solar zenith angle of) 48.2°, where the visible light radiation is assumed to be from 400 nm to 700 nm.

(1-TOPV)*opaque cell efficiency*AM1.5 radiation==TOPV*GLASS*375W/m² [Formula 1]

Where AM1.5 radiation is assumed to be 1000 W/m², where TOPV is the visible transmission of the OPV solar cell and GLASS is the optical transparency of the second substrate. In Formula 1, the electricity generated equals (1-TOPV)*opaque cell efficiency*AM1.5 radiation, and the heat flow through the window is given by=TOPV*GLASS*375 W/m².

In an embodiment, a window may be designed to transmit a portion of the visible light passing through it. The window may include an integrated organic photovoltaic cell such that the electricity generated may exceed the heat flow through the window under ambient solar irradiation. In an embodiment, the electricity generated versus the heat flow may be measured on a smaller section of the device. That is, testing may be performed on smaller portions of the windows than the entire window. A window may be designed to transmit a portion of the visible light passing through it, where the window includes an integrated photovoltaic cell such that the transmission of visible light is essentially uniform across the window (we need to allow for gradual changes but not embedded silicon wafers or other non-transparent regions)

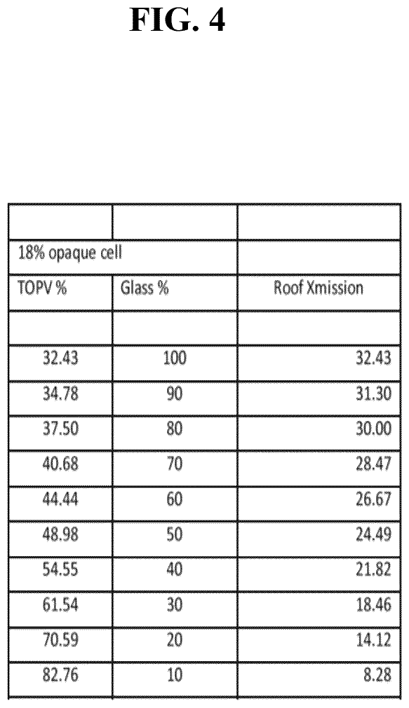

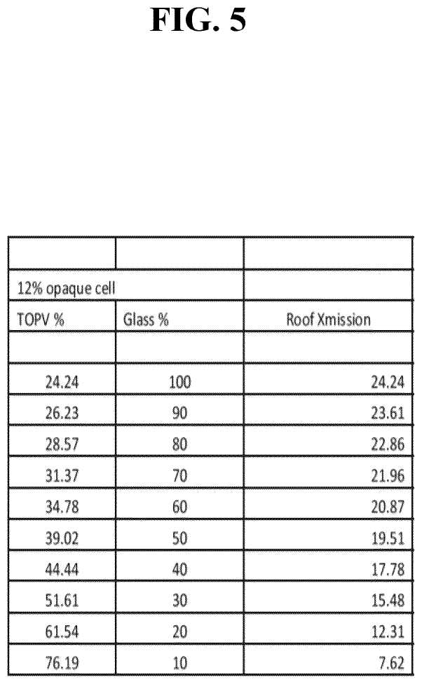

FIG. 4 shows calculation results relating sunroof glass transparency (“Glass %”) to solar cell transparency (“TOPV”) to show the transmission of the sunroof (“Roof Xmission”) such that electricity generated exceeds heat flow into vehicle for OPV with 18% opaque cell efficiency according to an embodiment of the disclosed subject matter. FIG. 5 shows a similar table for a 12% opaque cell efficiency according to another embodiment of the disclosed subject matter. The sunroof transmission may be the product of the OPV transparency and the transparency of the second substrate, where the product equals TOPV*GLASS. Opaque cell efficiency may be the efficiency of the solar cell assuming it absorbed all the incident radiation and was not transparent.

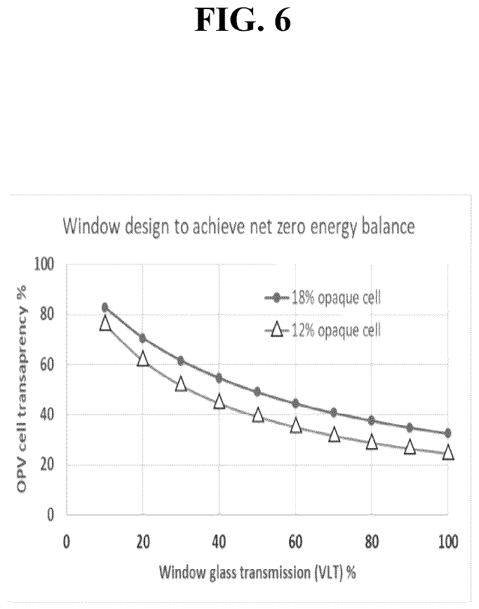

FIG. 6 shows a plot relating sunroof glass transparency (“VLT”) to solar cell transparency (“OVP cell transparency”) such that electricity generated exceeds heat flow into vehicle for OPV with both 12% and 18% opaque cell efficiencies. Points on the graph below the plotted lines represent design criteria where the OPV cell can generate more energy than enters the vehicle as heat. That is, for a given opaque cell efficiency, points below the curve shown in FIG. 6 represent a design where the OPV generates more energy than the window allows in as heat.

In an embodiment, the TOPV may be a thin solar cell. In an embodiment, the TOPV may be combined with the glass substrate with the TOPV facing closer to the ambient light and farther from the vehicle, building, or structure. In an embodiment, the device may have continuous and constant optical transmission over 80% of the active area of the device (i.e., window, skylight, or sunroof). In an embodiment, the power generated by the TOPV may be larger than the heat entering the car through the window. In an embodiment, the TOPV may have an efficiency greater than 8% and a cell transparency greater than 40%. In an embodiment, the TOPV may have an efficiency greater than 10% and a cell transparency greater than 40%. In an embodiment, the TOPV may have an efficiency greater than 5% and a cell transparency greater than 60%. In an embodiment, the TOPV may have an efficiency greater than 7% and a cell transparency greater than 60%.

In an embodiment, the TOPV transmission may be greater than 40% and the window transparency is larger than 40%. In an embodiment, the TOPV transmission may be greater than 30% and the window transparency is greater than 60%. In an embodiment, the TOPV transmission may be greater than 60% and the window transparency is greater than 20%. In an embodiment, the window transparency is less than 50%.

In one aspect, an OPV device may include a compound. In one embodiment, the OPV device may include an anode, a cathode, and an active material positioned between the anode and cathode, where the active material includes an acceptor and a donor.

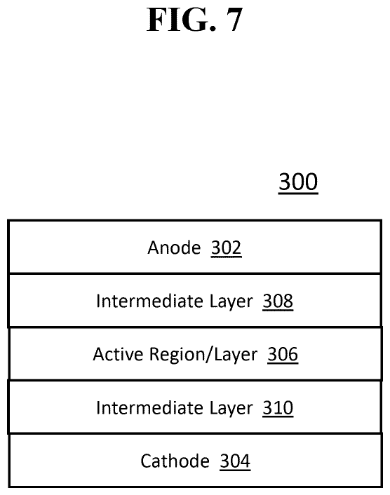

In one embodiment, the OPV device of the disclosed subject matter may include a single-junction organic photovoltaic device 100 having a non-fullerene acceptor compound as shown in FIG. 7. In one embodiment, the OPV device shown in FIG. 7 may have two electrodes, including an anode 302 and a cathode 304 in superposed relation. The OVP device may have at least one donor composition, and may have at least one acceptor composition, where the donor-acceptor material or active layer 306 is positioned between the two electrodes 302 and 304. In one embodiment, one or more intermediate layers 308 may be positioned between the anode 302 and the active layer 306. Additionally, or alternatively, one or more intermediate layers 310 may be positioned between the active layer 306 and cathode 304.

In one embodiment, the anode 302 may be a conducting oxide, thin metal layer, and/or conducting polymer. In one embodiment, the anode 302 may be a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode 302 may be a metal layer. Exemplary metals for the metal layer include, but are not limited to, Ag, Au, Pd, Pt, Ti, V, Zn, Sn, Al, Co, Ni, Cu, Cr, and combinations thereof. In one embodiment, the metal layer may be a thin metal layer. In one embodiment, the anode 302 may be a conductive polymer. Exemplary conductive polymers include, but are not limited to, polyanaline (PANI), or 3,4-polyethyl-enedioxythiophene: polystyrenesulfonate (PEDOT: PSS). In one embodiment, a thickness of the anode 302 may be between about 0.1-100 nm. In one embodiment, thickness of the anode 302 may be between about 1-10 nm. In one embodiment, thickness of the anode 302 may be between about 0.1-10 nm. In one embodiment, thickness of the anode 102 may be between about 10-100 nm. In one embodiment, the anode 302 may include a transparent or semi-transparent conductive material.

In one embodiment, the cathode 304 may include a conducting oxide, a metal layer, or conducting polymer. Exemplary conducting oxide, metal layers, and conducting polymers are described elsewhere herein. In one embodiment, the cathode 304 may be a thin metal layer. In one embodiment, the cathode 304 may be a metal or metal alloy. In one embodiment, the cathode 304 may be Ca, Al, Mg, Ti, W, Ag, Au, or another appropriate metal, or an alloy thereof. In one embodiment, the thickness of the cathode 304 may be between about 0.1-100 nm. In one embodiment, the thickness of the cathode 304 may be between about 1-10 nm. In one embodiment, the thickness of the cathode 304 may be between about 0.1-10 nm. In one embodiment, the thickness of the cathode 304 may be between about 10-100 nm. In one embodiment, the cathode 304 may be a transparent or semi-transparent conductive material.

In one embodiment, the OPV device may include one or more charge collecting/transporting intermediate layers positioned between an electrode 302, 304, and the active region or layer 306. In one embodiment, the OPV device may include intermediate layer 308. In one embodiment, the OPV device may include intermediate layer 310. In one embodiment, the OPV device may include both intermediate layers 308 and 310. In one embodiment, the intermediate layer 308 may be a metal oxide. In one embodiment, the intermediate layer 310 may include a metal oxide. Exemplary metal oxides include, but are not limited to, MoO₃, V2O₅, ZnO, and TiO₂. In one embodiment, the first intermediate layer 308 may have the same composition as the second intermediate layer 310. In one embodiment, the first intermediate layer 308 and the second intermediate layer 310 may have different compositions. In one embodiment, the thickness of the intermediate layer 308 and the intermediate layer 310 may be each independently between about 0.1-100 nm. In one embodiment, the thickness of intermediate layer 308 and the intermediate layer 310 may be each independently between about 1-10 nm. In one embodiment, the thickness of the intermediate layer 308 and the intermediate layer 310 may be each independently between about 0.1-10 nm. In one embodiment, the thickness of intermediate layer 308 and the intermediate layer 310 may be each independently between about 10-100 nm.

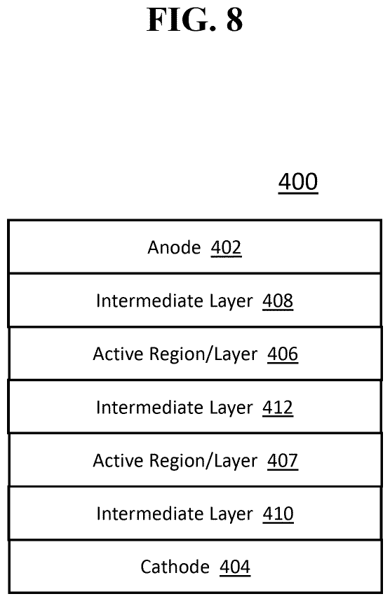

In one embodiment, the OPV device may have a plurality of layers of a tandem or multi-junction photovoltaic device 400 having a non-fullerene acceptor compound as shown in FIG. 8. In one embodiment, the OPV device may include two electrodes having an anode 402 and a cathode 404 in superposed relation, at least one donor composition, and at least one acceptor composition positioned within a plurality of active layers or regions 406 and 407 between the two electrodes 402 and 404. Additional active layers or regions may be included. In one embodiment, the anode 402 and the cathode 404 may be each independently include a conducting oxide, thin metal layer, or conducting polymer. Exemplary conducting oxides, metal layers, and conducting polymers are described elsewhere herein.

In one embodiment, the OPV device shown in FIG. 8 may include one or more intermediate layers 408 positioned between the anode 402 and a first active layer 406. Additionally, or alternatively, at least one intermediate layer 410 may be positioned between the second active layer 407 and the cathode 404. In one embodiment, the OPV device may include one or more intermediate layers 412 positioned between the first active layer 406 and the second active layer 407. In one embodiment, the OPV device may include intermediate layer 408. In one embodiment, the OPV device may include intermediate layer 410. In one embodiment, the OPV device may include intermediate layer 412. In one embodiment, the OPV device may include both intermediate layers 408 and 410. In one embodiment, the OPV device may include both intermediate layers 408 and 412. In one embodiment, the OPV device may include both intermediate layers 410 and 412. In one embodiment, the OPV device comprises may include intermediate layers 408, 410, and 412. In one embodiment, intermediate layer 408 may include a metal oxide. In one embodiment, intermediate layer 410 may include a metal oxide. In one embodiment, the intermediate layer 412 may be a metal oxide. Exemplary metal oxides are described elsewhere herein. Exemplary thicknesses for intermediate layers 408, 410, and 412 are described elsewhere herein.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A device comprising:
a first photovoltaic (PV) cell on a first substrate, wherein the first OPV has a first transparency and a first efficiency, and wherein a first portion of light is absorbed by the first OPV based on the first efficiency to generate electricity; and
a second substrate adjacent to the first PV,
wherein a second portion of light passes through the first PV based on the first transparency and passes through the second substrate.

2. The device of claim 1, wherein the first PV is an organic PV (OPV).

3. The device of claim 1, wherein the second substrate has a second transparency and is on an opposite side of the first PV from the first substrate.

4. The device of claim 3, wherein the first substrate or the second substrate is a protective barrier.

5. The device of claim 1, wherein the electricity generated by the first portion of light absorbed by the first PV exceeds the heat flow caused by the second portion of light under ambient solar irradiation.

6. The device of claim 1, wherein the first PV is a thin film solar cell comprising at least one selected from a group consisting of: an organic thin film solar cell, a CdTe (cadmium telluride) solar cell, and a perovskite solar cell.

7. The of claim 1, wherein the first PV is closer to the ambient light than the first substrate.

8. The device of claim 1, wherein the first substrate is glass or plastic.

9. The device of claim 1, wherein the first substrate or the second substrate is tinted glass, and wherein the first PV is a thin film solar cell that is at least one selected from a group consisting of: an organic thin film solar cell, a CdTe (cadmium telluride) solar cell, and a perovskite solar cell.

10. The device of claim 1, wherein the first PV has a first transparency greater than 40% and a first efficiency greater than 8%.

11. The device of claim 1, wherein the first PV has a first transparency greater than 40% and a first efficiency greater than 10%.

12. The device of claim 1, wherein the first PV has a first transparency greater than 60% and a first efficiency greater than 5%.

13. The device of claim 1, wherein the first PV has a first transparency greater than 60% and a first efficiency greater than 7%.

14. The device of claim 1, wherein the first PV has a first transparency that is greater than 40% and the first substrate has a second transparency greater than 40%.

15. The device of claim 1, wherein the first PV has a first transparency that is greater than 30% and the first substrate has a second transparency greater than 60%.

16. The device of claim 1, wherein the first PV has a first transparency that is greater than 60% and the first substrate has a second transparency greater than 20%.

17. The device of claim 1, wherein the first substrate has a second transparency less than 50%.

18. The device of claim 1, wherein the first substrate and the second substrate are the same material.

19. The device of claim 1, wherein the second portion of light passes through the second substrate based on the second transparency.
